(19) United States
(12) Patent Application Publication
(10) Pub. No.: US 2023/0337425 A1
(43) Pub. Date: Oct. 19, 2023

(54) Memory Structure And Method For Forming The Same

(71) Applicant: Shanghai Huahong Grace Semiconductor Manufacturing Corporation, Shanghai (CN)

(72) Inventors: Binghan LI, Shanghai (CN); Tao YU, Shanghai (CN)

(73) Assignee: Shanghai Huahong Grace Semiconductor Manufacturing Corporation, Shanghai (CN)

(21) Appl. No.: 18/190,305

(22) Filed: Mar. 27, 2023

(30) Foreign Application Priority Data
Apr. 19, 2022 (CN) 202210412974.5

(51) Int. Cl. H10B 41/30; H01L 29/423

(52) U.S. Cl. CPC H10B 41/30; H01L 29/42328

(57) ABSTRACT

The present disclosure provides a memory structure and a method for forming the same. The memory structure includes: a substrate; a plurality of discrete composite structures disposed on the substrate, wherein a first opening is formed between adjacent composite structures, and each composite structure includes a first conductive structure, a floating gate structure disposed on both sides of the first conductive structure, an erasing gate structure disposed on the floating gate structure, a first isolation structure, a second isolation structure and a third isolation structure disposed on the erasing gate structure; a plurality of mutually independent source doped regions disposed in the substrate, wherein the plurality of source doped regions are in contact with bottom surfaces of the first conductive structure and the floating gate structure; and a word line structure disposed in the first opening. Therefore, the performance and integration of the memory structure can be improved.

### CROSS-REFERENCE TO RELATED APPLICATIONS

This application claims the benefit of priority to Chinese patent application No. 202210412974.5, filed on Apr. 19, 2022, the entire disclosures of which are incorporated herein by reference.

### TECHNICAL FIELD

The present disclosure relates to the technical field of semiconductors, and more particularly to a memory structure and a method for forming the memory structure.

### BACKGROUND

Flash memory has become a research hotspot in nonvolatile memory because of its convenience, high storage density and good reliability. Since first flash memory came out in the 1980s, with a development of technology and a storage demand of various electronic products, the flash memory has been widely used in mobile communication devices such as mobile phones, notebooks, handheld computers and USB flash drives.

The flash memory is a non-volatile memory, which controls switch of a gate channel by changing a critical voltage of a transistor or a storage unit to achieve a purpose of storing data, so that data stored in the memory will not disappear due to power interruption. Now, the flash memory has occupied most of the market share of nonvolatile semiconductor memory, and has become the fastest growing nonvolatile semiconductor memory. At present, the widely used flash memory is a split gate structure.

However, the performance and reliability of the existing flash memory still need to be improved.

### SUMMARY

The present disclosure provides a memory structure and a method for forming the memory structure, in order to improve the performance and integration of the flash memory.

According to an aspect of the present disclosure, a memory structure includes: a substrate; a plurality of discrete composite structures disposed on the substrate, wherein a first opening is formed between adjacent composite structures, and each composite structure includes a first conductive structure, a floating gate structure disposed on both sides of the first conductive structure, an erasing gate structure disposed on the floating gate structure, a first isolation structure, a second isolation structure and a third isolation structure disposed on the erasing gate structure, wherein the second isolation structure is disposed between the first conductive structure and the floating gate structure, the erasing gate structure and the first isolation structure, the third isolation structure is disposed on side surfaces of the first isolation structure, the erasing gate structure and the floating gate structure, and a side surface of the third isolation structure and a surface of the substrate are exposed through an inner wall surface of the first opening; a plurality of mutually independent source doped regions disposed in the substrate, wherein the plurality of source doped regions are in contact with bottom surfaces of the first conductive structure and the floating gate structure; and a word line structure disposed in the first opening.

According to some embodiments, the floating gate structure includes a floating gate dielectric layer and a floating gate electrode disposed on the floating gate dielectric layer.

According to some embodiments, the erasing gate structure includes a tunneling dielectric layer and an erasing gate electrode disposed on the tunneling dielectric layer.

According to some embodiments, a width of the erasing gate electrode is less than a width of the floating gate structure.

According to some embodiments, in a side of the erasing gate structure adjacent to the third isolation structure, a side of the erasing gate electrode is recessed relative to a side of the tunneling dielectric layer.

According to some embodiments, the third isolation structure includes: a first side wall disposed on side surfaces of the first isolation structure and the erasing gate electrode, and a second side wall disposed on side surfaces of the first side wall, the tunneling dielectric layer and the floating gate structure, wherein a side surface of the second side wall is exposed through the first opening.

According to some embodiments, the memory structure further includes: a first protective layer disposed between the second isolation structure and the first conductive structure.

According to some embodiments, the first protective layer is made of polysilicon or silicon nitride.

According to some embodiments, the memory structure further includes: a contact layer disposed on a top surface of the first conductive structure.

According to some embodiments, the memory structure further includes: a second protective layer disposed on a top surface of the first conductive structure.

According to some embodiments, wherein the word line structure includes: a word line dielectric film disposed on the inner wall surface of the first opening, and two word line films respectively disposed on opposite side surfaces of the word line dielectric film, wherein a word line opening is formed between the two word line films, and side surfaces of the two word line films and a part of a surface of the word line dielectric film on a bottom surface of the first opening are exposed through the word line opening.

According to some embodiments, the memory structure further includes: a third side wall disposed on the side surfaces of the two word line films.

According to some embodiments, the memory structure further includes: an interlayer dielectric layer disposed on the plurality of composite structures and the word line structure, wherein a surface of the interlayer dielectric layer is higher than a top surface of the plurality of composite structures; and a plurality of bit lines disposed in the interlayer dielectric layer, wherein the plurality of bit lines are also disposed in the word line opening.

According to another aspect of the present disclosure, a method for forming the memory structure includes: providing a substrate; forming a plurality of discrete composite structures on the substrate, wherein a first opening is formed between adjacent composite structures, and each composite structure includes a first conductive structure, a floating gate structure disposed on both sides of the first conductive structure, an erasing gate structure disposed on the floating gate structure, a first isolation structure, a second isolation structure and a third isolation structure disposed on the erasing gate structure, wherein the second isolation structure is disposed between the first conductive structure and the floating gate structure, the erasing gate structure and the first isolation structure, the third isolation structure is disposed on side surface of the first isolation structure, the erasing gate structure and the floating gate structure, and a side surface of the third isolation structure and a surface of the substrate are exposed through an inner wall surface of the first opening; forming a plurality of mutually independent source doped regions in the substrate during forming the plurality of composite structures, wherein the plurality of source doped regions are in contact with bottom surfaces of the first conductive structure and the floating gate structure; and forming a word line structure in the first opening after forming the plurality of composite structures.

According to some embodiments, forming the plurality of composite structures includes: forming an initial floating gate layer on the substrate, an initial erasing gate layer on the initial floating gate layer, and a mask layer on the initial erasing gate layer, wherein the mask layer is provided with a plurality of mask openings, a part of a surface of the initial erasing gate layer is exposed through the plurality of mask openings; forming the first isolation structure on side surfaces of the plurality of mask openings; etching the initial erasing gate layer and the initial floating gate layer with the mask layer and the first isolation structure as a mask until the surface of the substrate is exposed so that a third opening is formed in the initial erasing gate layer and the initial floating gate layer; forming the second isolation structure on side surfaces of the first isolation structure and the third opening; and forming the first conductive structure in the plurality of mask openings and the third opening and forming a second protective layer on a top surface of the first conductive structure after forming the second isolation structure.

According to some embodiments, the method further includes: forming a first protective layer on a side surface of the second isolation structure during forming the second isolation structure.

According to some embodiments, forming the second isolation structure includes: forming a second isolation structure material film on a surface of the mask layer, a surface of the first isolation structure and an inner wall surface of the third opening; forming a first protective material film on a surface of the second isolation structural material film; and etching the first protective material film and the second isolation structure material film by an anisotropic etching process until a top surface of the mask layer and a bottom surface of the third opening are exposed.

According to some embodiments, forming the plurality of mutually independent source doped regions in the substrate during forming the plurality of composite structures includes: performing an ion implantation on the substrate exposed through a bottom of the third opening with the mask layer, the first isolation structure and the second isolation structure as a mask before forming the first conductive structure; and diffusing the implanted ions into the substrate below the initial floating gate layer on two sides of the third opening.

According to some embodiments, forming the plurality of composite structures further includes: removing the mask layer after forming the first conductive structure and the second protective layer; patterning the initial erasing gate layer according to the second protective layer and the first isolation structure to form the erasing gate structure after removing the mask layer; and patterning the initial floating gate layer according to the second protective layer and the first isolation structure to form the floating gate structure after forming the erasing gate structure.

According to some embodiments, the initial erasing gate layer includes an initial tunneling dielectric layer and an initial erasing gate electrode layer on the initial tunneling dielectric layer, and the erasing gate structure includes a tunneling dielectric layer and an erasing gate electrode on the tunneling dielectric layer.

According to some embodiments, the third isolation structure includes: a first side wall on side surfaces of the first isolation structure and the erasing gate electrode, and a second side wall on side surfaces of the first side wall, the tunneling dielectric layer and the floating gate structure, and a side surface of the second side wall is exposed through the first opening.

According to some embodiments, forming the third isolation structure includes: forming the first side wall during patterning the initial erasing gate layer according to the second protective layer and the first isolation structure to form the erasing gate structure; and forming the second side wall on the side surfaces of the first side wall, the tunneling dielectric layer and the floating gate structure after forming the floating gate structure.

According to some embodiments, patterning the initial erasing gate layer according to the second protective layer and the first isolation structure to form the erasing gate structure includes: etching the initial erasing gate electrode layer with the second protective layer and the first isolation structure as a mask until a surface of the initial tunneling dielectric layer is exposed to form the erasing gate electrode; forming the first side wall on the side surfaces of the first isolation structure and the erasing gate electrode; and etching the initial tunneling dielectric layer with the second protective layer, the first isolation structure and the first side wall as a mask until a surface of the initial floating gate layer is exposed to form the tunneling dielectric layer.

According to some embodiments, patterning the initial floating gate layer according to the second protective layer and the first isolation structure to form the floating gate structure after forming the erasing gate structure includes: etching the initial floating gate layer with the second protective layer, the first isolation structure and the first side wall as a mask until the surface of the substrate is exposed.

According to some embodiments, forming the word line structure in the first opening after forming the plurality of composite structures includes: forming a word line dielectric material film on the plurality of composite structures and an inner wall surface of the first opening, wherein the word line dielectric material film on the inner wall surface of the first opening is taken as a word line dielectric film; forming an initial word line film on a surface of the word line dielectric material film; etching the initial work line film by an anisotropic etching process until a surface of the word line dielectric film is exposed through a bottom surface of the first opening; and forming two word line films on opposite side surfaces of the word line dielectric film, wherein a word line opening is formed between the two word line films, and side surfaces of the two word line films and a part of a surface of the word line dielectric film on the bottom surface of the first opening are exposed through the word line opening.

According to some embodiments, the method further includes: forming a third side wall on the side surfaces of the two word line films after forming the word line structure.

According to some embodiments, the method further includes: forming an interlayer dielectric layer on the plurality of composite structures and the word line structure after forming the word line structure, wherein a surface of the interlayer dielectric layer is higher than a top surface of the plurality of composite structures; and forming a plurality of bit lines in the interlayer dielectric layer, wherein the plurality of bit lines are also disposed in the word line opening.

According to some embodiments, the method further includes: forming a contact layer on a top surface of the first conductive structure after forming the word line structure.

The embodiments of the present disclosure have following beneficial effects:

According to some embodiments, the composite structure includes a first conductive structure, a floating gate structure disposed on both sides of the first conductive structure, an erasing gate structure disposed on the floating gate structure, a first isolation structure, a second isolation structure and a third isolation structure disposed on the erasing gate structure, wherein the second isolation structure is disposed between the first conductive structure and the floating gate structure, the erasing gate structure and the first isolation structure, and the third isolation structure is disposed on side surfaces of the first isolation structure, the erasing gate structure and the floating gate structure. A plurality of mutually independent source doped regions are disposed in the substrate, wherein surfaces of the plurality of source doped regions are in contact with bottom surfaces of the first conductive structure and the floating gate structure, and a word line structure is disposed in the first opening. Therefore, the present disclosure can improve the performance and integration of the memory structure while achieving a low reading voltage of the memory structure, a low risk of interference when reading data and a high accuracy of data reading.

### BRIEF DESCRIPTION OF THE DRAWINGS

FIG. 1 is a cross-sectional structural schematic view of an existing memory structure; and

FIGS. 2 to 19 are cross-sectional structural schematic views showing each step of a method for forming a memory structure according to an embodiment of the present disclosure.

### DETAILED DESCRIPTION

As described in the background, the performance and reliability of the existing flash memory still need to be improved. The following will be described in combination with the attached drawings.

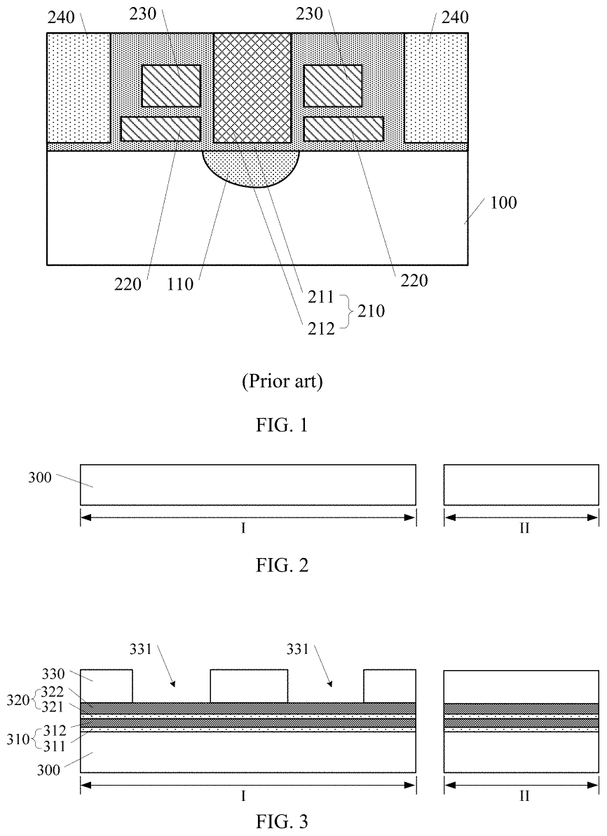

FIG. 1 is a cross-sectional structural schematic view of an existing memory structure.

Referring to FIG. 1, the memory structure includes a substrate 100 and a plurality of composite structures disposed on the substrate 100.

Each composite structure includes an erasing gate structure 210 disposed on the substrate 100, a floating gate structure 220 disposed on two sides of the erasing gate structure 210, a control gate structure 230 disposed on the floating gate structure 220 and a word line structure 240 respectively disposed on two sides of the floating gate structure 220 and the erasing gate structure 230. The erasing gate structure 210 includes an erasing gate oxide layer 211 and an erasing gate electrode 212 disposed on the erasing gate oxide layer 211.

The substrate 100 is provided with a source doped region 110 disposed below the erasing gate structure 210.

The control gate structure 230 is used to couple voltage to the floating gate structure 220, the erasing gate structure 210 is used to erase data, and the word line structure 240 is used to read data. Therefore, the word line structure 240 can only be used for reading data, so that the word line structure 240 is not affected by an erasing voltage, thus reducing the read voltage and the risk of interference when reading data.

However, in the above-mentioned memory structure, the erasing gate structure 210 is disposed above the source doped region 110. Therefore, on the one hand, the erasing gate oxide layer 211 is disposed between the source doped region 110 and the erasing gate electrode 212, which results in high parasitic resistance at the source doped region 110 and the erasing gate structure 210, resulting in poor performance of the memory structure; on the other hand, a structure (not shown) for connecting the source doped region 110 below each erasing gate structure 210 needs to be formed in the substrate 100 outside a part of the substrate 100 below the composite structures 200, so as to lead out the source doped region 110 below each erasing gate structure 210, thus causing poor integration of the memory structure. Therefore, the existing memory structure has poor performance and low integration.

The embodiments of the present disclosure provide a memory structure and a method for forming the memory structure. The memory structure includes: a substrate; a plurality of discrete composite structures disposed on the substrate, wherein a first opening is formed between adjacent composite structures, and each composite structure includes a first conductive structure, a floating gate structure disposed on both sides of the first conductive structure, an erasing gate structure disposed on the floating gate structure, a first isolation structure, a second isolation structure and a third isolation structure disposed on the erasing gate structure, wherein the second isolation structure is disposed between the first conductive structure and the floating gate structure, the erasing gate structure and the first isolation structure, the third isolation structure is disposed on side surfaces of the first isolation structure, the erasing gate structure and the floating gate structure, and a side surface of the third isolation structure and a surface of the substrate are exposed through an inner wall surface of the first opening; a plurality of mutually independent source doped regions disposed in the substrate, wherein the plurality of source doped regions are in contact with bottom surfaces of the first conductive structure and the floating gate structure; and a word line structure disposed in the first opening. Therefore, the performance and integration of the memory structure can be improved.

In order to make above purposes, features and beneficial effects of the present disclosure more obvious and understandable, specific embodiments of the present disclosure will be described in detail with the attached drawings.

FIGS. 2 to 19 are cross-sectional structural schematic views showing each step of a method for forming a memory structure according to an embodiment of the present disclosure.

Referring to FIG. 2, a substrate 300 is provided.

In some embodiments, the substrate 300 includes a memory area I and a logic area II.

It should be noted that for the convenience of illustration, a part of the memory area I and a part of the logic area II are schematically shown in FIG. 2.

The memory area I is used to form a memory structure, and the logic area II is used to form a logic circuit for logic control of the memory structure.

In some embodiments, the material of the substrate 300 is silicon; in other embodiments, the material of the substrate may also be germanium, silicon germanium, silicon carbide, gallium arsenide or indium gallium.

Then, a plurality of discrete composite structures are formed on the substrate 300, and in the process for forming the composite structures, a plurality of independent source doped regions are formed in the substrate 300. Referring to FIGS. 3 to 14, the specific steps of forming the composite structures and the source doped regions are illustrated.

Referring to FIG. 3, an initial floating gate layer 310 is formed on the substrate 300, an initial erasing gate layer 320 is formed on the initial floating gate layer 310, and a mask layer 330 is formed on the initial erasing gate layer 320. A plurality of mask openings 331 are formed in the mask layer 330, and a part of a surface of the initial erasing gate layer 320 is exposed through the mask openings 331.

In some embodiments, the initial floating gate layer 310 includes an initial floating gate dielectric layer 311 and an initial floating gate electrode layer 312 disposed on a surface of the initial floating gate dielectric layer 311.

The initial floating gate layer 310 provides materials for subsequent formation of the floating gate structure. Specifically, the initial floating gate dielectric layer 311 provides materials for subsequent formation of the floating gate dielectric layer, and the initial floating gate electrode layer 312 provides materials for subsequent formation of the floating gate electrode.

In some embodiments, the material of the initial floating gate dielectric layer 311 includes silicon oxide.

In some embodiments, the material of the initial floating gate electrode layer 312 includes polysilicon.

In some embodiments, the method for forming the initial floating gate layer 310 includes: depositing the initial floating gate dielectric layer 311 on the surface of the substrate 300, and depositing the initial floating gate electrode layer 312 on the surface of the initial floating gate dielectric layer 311.

In some embodiments, the initial erasing gate layer 320 includes an initial tunneling dielectric layer 321 and an initial erasing gate electrode layer 322 disposed on the initial tunneling dielectric layer 321.

The initial erasing gate layer 320 provides materials for subsequent formation of the erasing gate structure. Specifically, the initial tunneling dielectric layer 321 provides materials for subsequent formation of the tunneling dielectric layer, and the initial erasing gate electrode layer 322 provides materials for subsequent formation of the erasing gate electrode.

In some embodiments, the material of the initial tunneling dielectric layer 321 includes silicon oxide.

In some embodiments, the material of the initial erasing gate electrode layer 322 includes polysilicon.

In some embodiments, the method for forming the initial erasing gate layer 320 includes: depositing the initial tunneling dielectric layer 321 on a surface of the initial floating gate layer 310, and depositing the initial erasing gate electrode layer 322 on a surface of the initial tunneling dielectric layer 321.

In some embodiments, the material of the mask layer 330 includes photoresist. Further, the method for forming the mask layer 330 includes: forming a photoresist material layer (not shown) on a surface of the initial erasing gate layer 320, and exposing and developing the photoresist material layer to form the mask layer 330.

In other embodiments, the mask layer includes a hard mask layer and a photoresist layer on a surface of the hard mask layer. Because the mask layer includes a hard mask layer, the stability of pattern transmission can be improved. Specifically, the method for forming the mask layer includes: forming the hard mask material layer on the surface of the initial erasing gate layer 320; forming the photoresist material layer on the surface of the hard mask material layer; exposing and developing the photoresist material layer to form the photoresist layer which exposes part of the surface of the hard mask material layer; etching the hard mask material layer with the photoresist layer as a mask until the initial erasing gate layer 320 is exposed to form the hard mask layer. Specifically, the material of the hard mask layer includes silicon nitride.

In some embodiments, the substrate 300 includes the memory area I and the logic area II, and the plurality of mask openings 331 are disposed in the mask layer 330 on the memory area I.

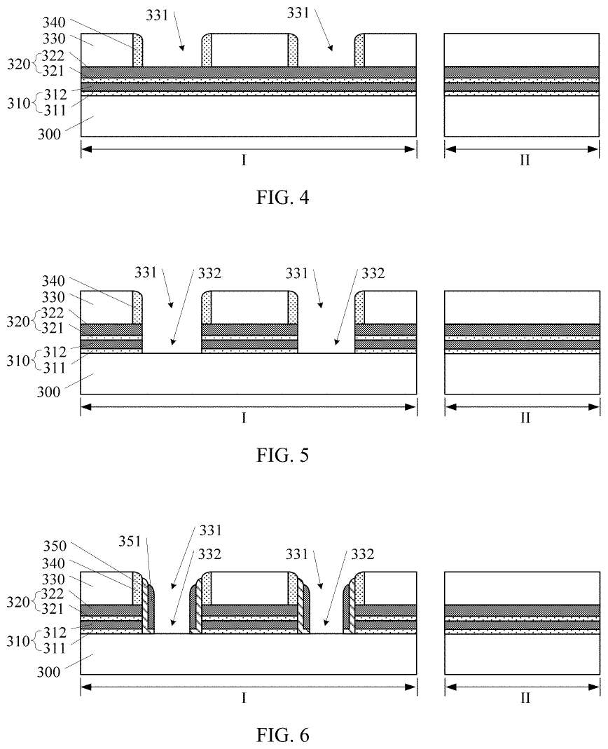

Referring to FIG. 4, a first isolation structure 340 is formed on a side surface of the mask openings 331.

In some embodiments, the method for forming the first isolation structure 340 includes: depositing a first isolation structure material film (not shown) on exposed surface of the initial erasing gate layer 320 and a surface of the mask layer 330; etching the first isolation structural material film by an anisotropic etching process until the surface of the initial erasing gate layer 320 and a top surface of the mask layer 330 are exposed.

In some embodiments, the process for etching the first isolation structure material film includes a plasma etching process.

In some embodiments, the material of the first isolation structure 340 includes a dielectric material.

In some embodiments, the material of the first isolation structure 340 includes silicon oxide.

Referring to FIG. 5, taking the mask layer 330 and the first isolation structure 340 as the mask, the initial erasing gate layer 320 and the initial floating gate layer 310 are etched until the surface of the substrate 300 is exposed, and a third opening 332 is formed in the initial erasing gate layer 320 and the initial floating gate layer 310 on the memory area I.

In some embodiments, the process for etching the initial erasing gate layer 320 and the initial floating gate layer 310 includes at least one of a dry etching process and a wet etching process.

Referring to FIG. 6, a second isolation structure 350 is formed on side surfaces of the first isolation structure 340 and the third opening 332.

In some embodiments, the mask opening 331 and the third opening 332 after the formation of the second isolation structure 350 can provide space for subsequent formation of a first conductive structure.

In some embodiments, the second isolation structure 350 is also disposed at partial bottom surface of the third opening 332.

In some embodiments, the material of the second isolation structure 350 includes silicon oxide.

In some embodiments, in the process for forming the second isolation structure 350, a first protective layer 351 is formed on a side surface of the second isolation structure 350.

In some embodiments, the method for forming the second isolation structure 350 and the first protective layer 351 includes: depositing a second isolation structure material film (not shown) on the surface of the mask layer 330, a surface of the first isolation structure 340, and an inner wall surface of the third opening 332; depositing a first protective material film (not shown) on a surface of the second isolating structural material film; etching the first protective material film and the second isolation structure by an anisotropic etching process until the top surface of the mask layer 330 and the bottom surface of the third opening 332 are exposed.

As the first protective material film is formed on the surface of the second isolating structure material film, when etching the first protective material film and the second isolating structure material film by an anisotropic etching process, the second isolating structure material film on a side of the first isolating structure 340 can be protected by the first protective material film, thus reducing or avoiding loss of the second isolation structure material film on the side of the first isolation structure 340 when etching the second isolating structure material film. Thus, the second isolation structure 350 with more accurate film thickness is formed, which further improves the performance of the memory structure.

In some embodiments, the material of the first protective layer 351 is the same as that of the subsequently formed first conductive structure to ensure the stability of the conductivity and further reduce the parasitic resistance.

Specifically, the material of the first protective layer 351 includes polysilicon.

In other embodiments, the material of the first conductive layer includes silicon nitride.

In other embodiments, the first protective layer is not formed. Specifically, the second isolation structure is only formed on the side surface of the first isolation structure 340 and the third opening 332. Moreover, the method for forming the second isolation structure includes: depositing a second isolation structure material film on the surface of the mask layer 330, the surface of the first isolation structure 340, and the inner wall surface of the third opening 332; etching the first protective material film by an anisotropic etching process until the top surface of the mask layer 330 and the bottom surface of the third opening 332 are exposed.

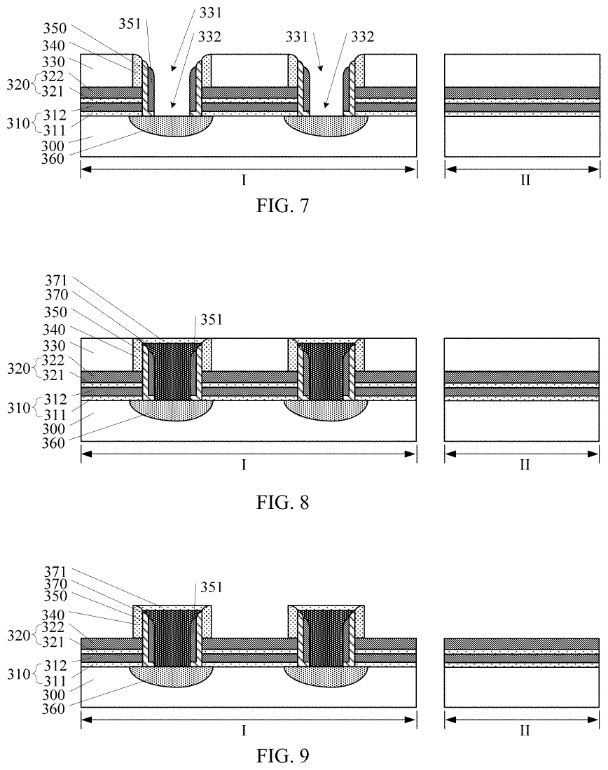

Referring to FIG. 7, a plurality of mutually independent source doped regions 360 are formed in the substrate 300 on the memory area I.

A surface of the source doped regions 360 is in contact with bottom surfaces of the first conductive structure 370 (as shown in FIG. 14) and a floating gate structure 410 (as shown in FIG. 14) formed subsequently, so as to realize voltage coupling to the floating gate structure 410.

In some embodiments, the method of forming the source doped regions 360 includes: performing ion implantation on the substrate 300 exposed through the bottom of the third opening 332 with the mask layer 330, the first isolation structure 340 and the second isolation structure 350 as a mask, and diffusing the implanted ions into the substrate 300 below the initial floating gate layer 310 at two sides of the third opening 332.

Since the implanted ions diffuse into the substrate 300 below the initial floating gate layer 310 at two sides of the third opening 332, the source doped regions 360 can be in contact with the bottom surface of the floating gate structure 410 (as shown in FIG. 14) on two sides of the first conductive structure 370 (as shown in FIG. 14) to realize a voltage coupling to the floating gate structure 410.

Moreover, since the source doped regions 360 are formed by performing an ion implantation on the substrate 300 exposed through the bottom of the third opening 332 by taking the mask layer 330, the first isolation structure 340 and the second isolation structure 350 as the mask, the source doped regions 360 can be formed in a self-aligned manner based on the mask layer 330, thus the number of photolithographic patterns in the process for forming the memory structure can be reduced (a separate photolithographic pattern is not needed to form the source doped regions 360), and the process for forming the memory structure can be simplified.

Referring to FIG. 8, after the source doped regions 360 are formed, the first conductive structure 370 is formed in the mask opening 331 and the third opening 332, and a second protective layer 371 is formed on a top surface of the first conductive structure 370.

In some embodiments, the material of the first conductive structure 370 includes polysilicon.

In some embodiments, the material of the second protective layer 371 includes silicon oxide.

The function of the second protective layer 371 is to protect the first conductive structure 370, so as to reduce the risk of oxidation of the first conductive structure 370 in the subsequent formation steps, and improve the performance and reliability of the formed memory structure.

On the one hand, the second protective layer 371 can serve as a mask when the initial erasing gate layer 320 and the initial floating gate layer 310 are subsequently patterned; on the other hand, the second protective layer 371 can also separate the material of the word line structure from the first conductive structure 370 in the subsequent process of forming the word line structure, and serve as a stop position of the etching step when etching the material of the word line structure. Therefore, not only the source doped regions 360, but also the erasing gate structure, the floating gate structure and the bit line structure can be formed in a self-aligned manner. Thus, the process for forming the memory structure can be further simplified.

In some embodiments, the method for forming the first conductive structure 370 and the second protective layer 371 includes: forming a first conductive structure material layer (not shown) in the mask opening 331, in the third opening 332, and on the mask layer 33, wherein a surface of the first conductive structure material layer is higher than the top surface of the mask layer 330; flatting the first conductive structure material layer until the top surface of the mask layer 330 is exposed to form the initial first conductive structure (not shown); oxidizing a surface layer on the top surface of the initial first conductive structure to form the first conductive structure 370 and the second protective layer 371 on the top surface of the first conductive structure 370.

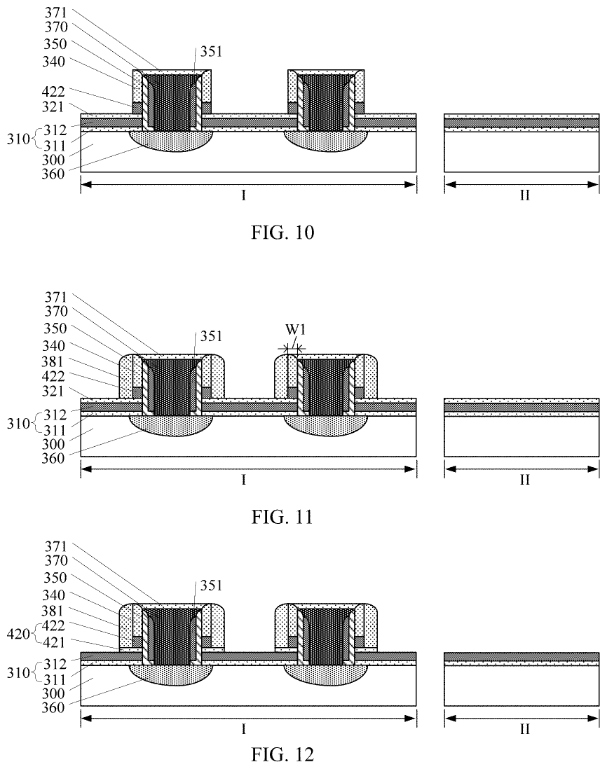

Referring to FIG. 9, after the first conductive structure 370 and the second protective layer 371 are formed, the mask layer 330 is removed.

In some embodiments, the process for removing the mask layer 330 includes an ashing process.

In other embodiments, the process for removing the mask layer 330 includes a wet cleaning process. Specifically, a chemical used in the wet cleaning process includes phosphoric acid.

Next, according to the second protective layer 371 and the first isolation structure 340, the initial erasing gate layer 320 is patterned to form the erasing gate structure.

In some embodiments, in the process for patterning the initial erasing gate layer 320 according to the second protective layer 371 and the first isolation structure 340, a first side wall for forming the third isolation structure is formed.

FIGS. 10 to 12 illustrate specific steps of forming the erasing gate structure and the first side wall.

Referring to FIG. 10, taking the second protective layer 371 and the first isolation structure 340 as the mask, the initial erasing gate electrode layer 322 is etched until the surface of the initial tunneling dielectric layer 321 is exposed to form an erasing gate electrode 422.

In some embodiments, the material of the erasing gate electrode 422 includes polysilicon.

In some embodiments, the process for etching the initial erasing gate electrode layer 322 includes at least one of a dry etching process and a wet etching process.

Referring to FIG. 11, a first side wall 381 is formed on side surfaces of the first isolation structure 340 and the erasing gate electrode 422.

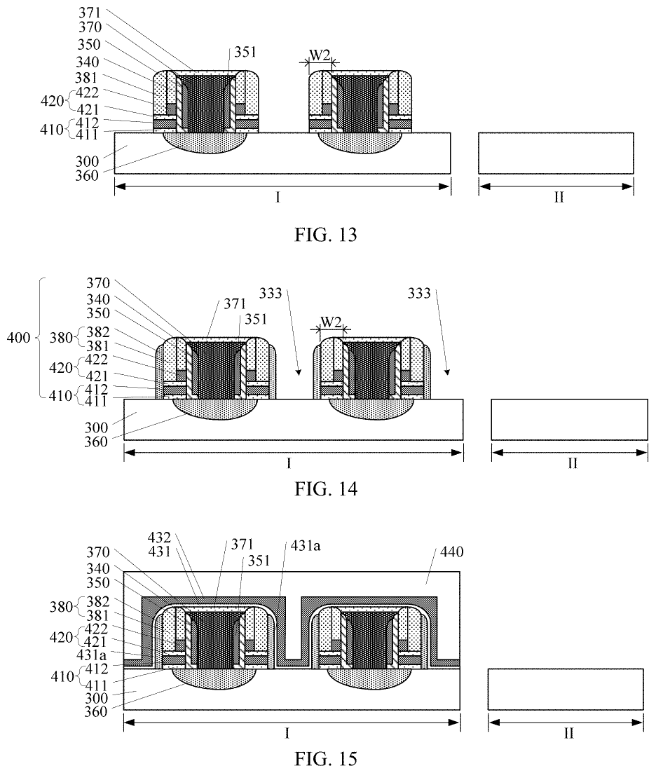

In some embodiments, the first side wall 381 can form a part of a third isolation structure 380 (as shown in FIG. 13). Therefore, a spacing between the first conductive structure 370 and subsequently formed word line structure is increased. Thus, the risk of short circuit between the first conductive structure 370 and the word line structure can be reduced, and the reliability of the memory structure can be improved.

Further, the first side wall 381 is also subsequently used as a part of the mask when the initial floating gate layer 310 is patterned to form the floating gate structure. Therefore, with the first side wall 381, a width W2 (as shown in FIG. 13) of subsequently formed floating gate structure 410 (as shown in FIG. 13) can be increased to form the floating gate structure 410 with a large width W2 while forming the erasing gate electrode 422 with a small width W1, so as to further reduce the voltage coupled to the erasing gate electrode 422, further reduce the erasing voltage, and better improve the performance of the memory structure.

In addition, the first side wall 381 can protect a side surface of the erasing gate electrode 422 during subsequent etching process for patterning the initial tunneling dielectric layer 321 and the initial floating gate layer 310 to reduce the damage to the erasing gate electrode 422. Thus, the performance of the memory structure can be further improved.

In some embodiments, the method for forming the first side wall 381 includes: depositing a first side wall material film (not shown) on the surface of the second protective layer 371, the surface of the first isolation structure 340, the side surface of the erasing gate electrode 422, and the surface of the initial tunneling dielectric layer 321; and etching the first side wall material film by an anisotropic etching process until the surface of the second protective layer 371, the top surface of the first isolation structure 340, and the surface of the initial tunneling dielectric layer 321 are exposed.

In some embodiments, the anisotropic etching process includes a plasma etching process.

The material of the first side wall 381 may include a dielectric material.

In some embodiments, the material of the first side wall 381 includes silicon oxide.

Referring to FIG. 12, the initial tunneling dielectric layer 321 is etched with the second protective layer 371, the first isolation structure 340 and the first side wall 381 as the mask until the surface of the initial floating gate layer 310 is exposed to form the tunneling dielectric layer 421 so as to form the erasing gate structure 420 on two sides of the first conductive structure 370.

In some embodiments, the erasing gate structure 420 includes the tunneling dielectric layer 421 and the erasing gate electrode 422 disposed on the tunneling dielectric layer 421.

In some embodiments, the material of the tunneling dielectric layer 421 includes silicon oxide.

In some embodiments, a width of the tunneling dielectric layer 421 is greater than a width of the erasing gate electrode 422.

Specifically, in a side of the erasing gate structure 420 adjacent to the first side wall 381, a side of the erasing gate electrode 422 is recessed relative to a side of the tunneling dielectric layer 421.

Specifically, the width of the tunneling dielectric layer 421 is equal to the width W2 (as shown in FIG. 13).

In some embodiments, the process for etching the initial tunneling dielectric layer 321 includes at least one of dry etching process and wet etching process.

Referring to FIG. 13, after the erasing gate structure 420 is formed, the initial floating gate layer 310 is patterned according to the second protective layer 371 and the first isolation structure 340, and the floating gate structure 410 is formed on two sides of the first conductive structure 370.

In some embodiments, after the erasing gate structure 420 is formed, the initial floating gate layer 310 is patterned according to the second protective layer 371 and the first isolation structure 340. The method of forming the floating gate structure 410 includes: etching the initial floating gate layer 310 with the second protective layer 371, the first isolation structure 340 and the first side wall 381 as the mask until the surface of the substrate 300 is exposed to form the floating gate structure 410.

In some embodiments, the floating gate structure 410 includes a floating gate dielectric layer 411 and a floating gate electrode 412 disposed on the floating gate dielectric layer 411.

In some embodiments, the material of the floating gate dielectric layer 411 includes silicon oxide.

In some embodiments, the material of the floating gate electrode 412 includes polysilicon.

In some embodiments, the width W2 of the floating gate structure 410 is greater than the width W1 of the erasing gate electrode 422.

Referring to FIG. 14, after the floating gate structure 410 is formed, a second side wall 382 is formed on the side surface of the first side wall 381, the side surface of the tunneling dielectric layer 421, and the side wall of the floating gate structure 410 to form a third isolation structure 380 on the side surfaces of the first isolation structure 340, the erasing gate structure 420 and the floating gate structure 410.

Specifically, in some embodiments, the third isolation structure 380 includes: the first side wall 381 disposed on the side surfaces of the first isolation structure 340 and the erasing gate electrode 422, and the second side wall 382 disposed on the side surfaces of the first side wall 381, the tunneling dielectric layer 421 and the floating gate structure 410.

The material of the second side wall 382 may include a dielectric material.

In some embodiments, the material of the second side wall 382 includes silicon oxide.

In some embodiments, the method of forming the second side wall 382 on the side surface of the first side wall 381, the side surface of the tunneling dielectric layer 421 and the side surface of the floating gate structure 410 includes: depositing a second side wall material film (not shown) on the surface of the second protective layer 371, the top surface of the first isolation structure 340, the surface of the first side wall 381, the side surface of the tunneling dielectric layer 421, the side surface of the floating gate structure 410 and the exposed surface of the substrate 300, and etching the second side wall material film by an anisotropic etching process until the surface of the second protective layer 371, the top surface of the first isolation structure 340, the top surface of the first side wall 381 and the surface of the substrate 300 are exposed.

Therefore, a plurality of composite structures 400 that are separated from each other are formed on the substrate 300 on the memory area I, and a first opening 333 is formed between adjacent composite structures 400.

Each composite structure 400 includes the first conductive structure 370, the floating gate structure 410 disposed on two sides of the first conductive structure 370, the erasing gate structure 420 disposed on the floating gate structure 410, the first isolation structure 340 disposed on the erasing gate structure 420, the second isolation structure 350 disposed between the first conductive structure 370 and the floating gate structure 410, the erasing gate structure 420 and the first isolation structure 340, and the third isolation structure 380 disposed on the side surfaces of the first isolation structure 340, the erasing gate structure 420 and the floating gate structure 410. The side surface of the third isolation structure 420 and the surface of the substrate 300 are exposed through the inner wall surface of the first opening 333.

In some embodiments, the side surface of the second side wall 382 is exposed through the first opening 333.

Next, after the composite structures 400 are formed, a word line structure is formed in the first opening 333.

In some embodiments, in the process for forming the word line structure, a plurality of logic gate structures are formed on the logic area II.

Referring to FIGS. 15 to 17, the steps of forming the word line structure and the plurality of logic gate structures are illustrated.

Referring to FIG. 15, a word line dielectric material film 431 is formed on the composite structure 400, the inner wall surface of the first opening 333 and the surface of the substrate 300 on the logic area II, and an initial word line film 432 is formed on a surface of the word line dielectric material film 431.

Specifically, the word line dielectric material film 431 on the inner wall surface of the first opening 333 is a word line dielectric film 431a.

In some embodiments, the material of the word line dielectric film 431a includes silicon oxide.

In some embodiments, the process for forming the word line dielectric material film 431 includes a deposition process, such as a chemical vapor deposition process, a physical vapor deposition process or an atomic layer deposition process.

The initial word line film 432 can provide materials for the subsequent formation of the word line film.

In some embodiments, the material of the initial word line film 432 includes polysilicon.

In some embodiments, the process for forming the initial word line film 432 includes a deposition process, such as a chemical vapor deposition, a physical vapor deposition or an atomic layer deposition.

Still referring to FIG. 15, after the initial word line film 432 is formed, a logic mask layer 440 is formed on the initial word line film 432 on the memory area I, and the logic mask layer 440 exposes the initial word line film 432 on the logic area II.

The logic mask layer 440 can protect the structures formed in and on the memory area I in the subsequent process for forming the plurality of logic gate structures on the logic area II.

In some embodiments, the material of the logic mask layer 440 includes photoresist.

Still referring to FIG. 15, the exposed initial word line film 432 and the word line dielectric material film 431 on the logic area II are etched with the logic mask layer 440 as the mask until the surface of the substrate 300 on the logic area II is exposed.

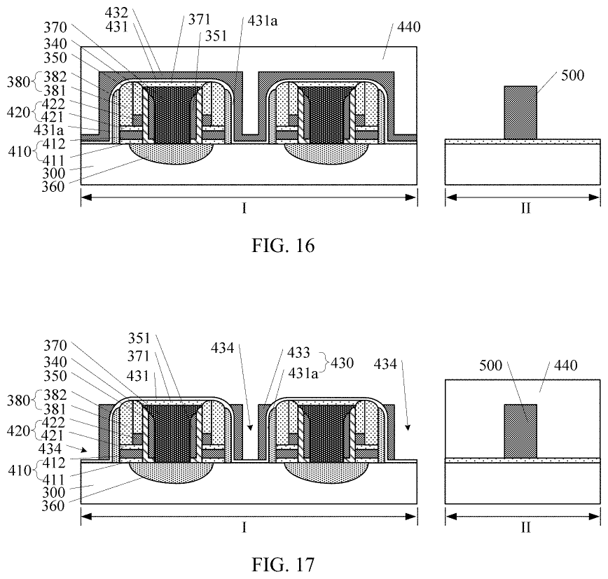

Referring to FIG. 16, a plurality of logic gate structures 500 are formed on the exposed surface of the logic area II.

In some embodiments, the plurality of logic gate structures 500 are used to form a plurality of high voltage MOS tubes and a plurality of low voltage MOS tubes.

In addition, for the convenience of illustration, only one logic gate structure 500 is schematically shown in FIG. 16.

In some embodiments, after the plurality of logic gate structures 500 are formed, the logic mask layer 440 is removed.

Referring to FIG. 17, after the plurality of logic gate structures 500 are formed, a memory mask layer 450 is formed on the logic area II, and the memory mask layer 450 exposes the initial word line film 432 on the memory area I.

The memory mask layer 450 can protect the substrate 300 on the logic area II and the plurality of logic gate structures 500 on the logic area II during the subsequent etching of the initial word line film.

In some embodiments, the material of the memory mask layer 450 includes photoresist.

Still referring to FIG. 17, after the memory mask layer 450 is formed, the initial word line film 432 is etched by an anisotropic etching process until the surface of the second protective layer 371 and the surface of the word line dielectric film 431a at the bottom of the first opening 333 are exposed, and two word line films 433 are formed on opposite side surfaces of the word line dielectric film 431a. A word line opening 434 is formed between the two word line films 433, and the side surfaces of the two word line films 433 and the bottom surface of the word line dielectric film 431a are exposed through the word line opening 434.

Therefore, a word line structure 430 is formed in the first opening 333.

In some embodiments, the word line structure 430 includes the word line dielectric film 431a disposed on the inner wall surface of the first opening 333, and two word line films 433 respectively disposed on the opposite side surfaces of the word line dielectric film 431a. The word line opening 434 is formed between the two word line films 433, and the side surfaces of the two word line films 433 and a part of the surface of the word line dielectric film 431a on the bottom surface of the first opening 333 are exposed through the word line opening 434.

In some embodiments, the material of the word line films 433 includes polysilicon.

In some embodiments, the anisotropic etching process for etching the initial word line film 432 includes a plasma etching process.

In some embodiments, the memory mask layer 450 is removed after the word line structure 430 is formed.

In other embodiments, the substrate does not include the logic area and does not include the logic gate structure. Therefore, after the initial word line film is formed, the initial word line film is directly etched by an anisotropic etching process until the surface of the word line dielectric film at the bottom of the first opening is exposed, and two word line films are formed on the opposite side surfaces of the word line dielectric film.

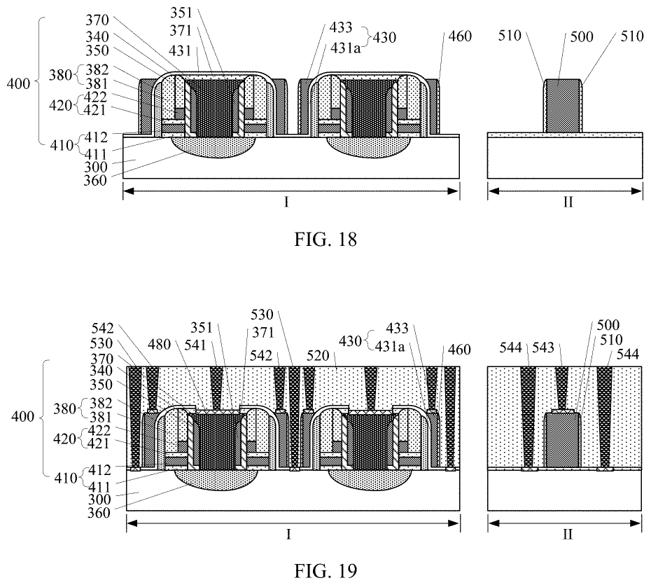

Next, referring to FIG. 18, a third side wall 460 is formed on the side surfaces of the word line films 433.

By forming the third side wall 460 on the side surfaces of the word line films 433, the risk of short circuit between the subsequently formed bit line structure and the word line films 433 can be reduced and thus the reliability of the memory structure can be better improved.

In some embodiments, the material of the third side wall 460 includes a dielectric material. Specifically, the material of the third side wall 460 includes silicon oxide.

In other embodiments, the third side wall is not formed.

In some embodiments, a fourth side wall 510 is formed on a side surface of the logic gate structure 500 while forming the third side wall 460.

In other embodiments, the fourth side wall is not formed.

In some embodiments, the method for forming the third side wall 460 and the fourth side wall 510 includes: forming a third side wall material film (not shown) on surfaces of the composite structure 400, the second protective layer 371, the word line structure 430, and the logic gate structure 500, and etching the third side wall material film by an anisotropic etching process until the top surface of the composite structure 400, the surface of the second protective layer 371, the bottom surface of the word line opening 434 and the top surface of the logic gate structure 500 are exposed.

Referring to FIG. 19, a contact layer 480 is formed on the top surface of the first conductive structure 370 by SAB (salicide block) process.

By forming the contact layer 480 on the top surface of the first conductive structure 370, the conductivity of the memory structure can be further improved, and thus the performance of the memory structure can be further improved.

In some embodiments, the contact layer 480 is also formed on the top surface of the word line films 433, the surface of the substrate 300 between the two word line films 433, the top surface of the logic gate structure 500, and the surface of the substrate 300 on two sides of the logic gate structure 500.

In some embodiments, the material of the contact layer 480 includes a metal silicide.

In other embodiments, the contact layer is not formed.

Next, still referring to FIG. 19, an interlayer dielectric layer 520 is formed on the composite structure 400 and the word line structure, and a surface of the interlayer dielectric layer 520 is higher than the top surface of the composite structure 400. A plurality of bit lines 530 are formed in the interlayer dielectric layer 520, and the bit lines 530 are also disposed in the word line opening 434.

In some embodiments, the bottom surfaces of the bit lines 530 are in contact with the contact layer 480 on the surface of the substrate 300 between the two word line films 433.

In other embodiments, no contact layer is formed on the surface of the substrate 300 between the two word line films 433, and the bit lines are in contact with the surface of the substrate between the two word line films.

In some embodiments, while forming the bit lines 530, a second conductive structure 541 is formed in the interlayer dielectric layer 520. The second conductive structure 541 is disposed on the first conductive structure 370, and the second conductive structure 541 is in contact with the contact layer 480 disposed on the top surface of the first conductive structure 370.

In some embodiments, while forming the bit lines 530, a third conductive structure 542 is formed in the interlayer dielectric layer 520 on the memory area I. The third conductive structure 542 is located on the word line films 433, and the third conductive structure 542 is in contact with the contact layer 480 on the top surface of the word line films 433.

In some embodiments, while forming the bit lines 530, a fourth conductive structure 543 and a fifth conductive structure 544 are formed in the interlayer dielectric layer 520 on the logic area II. The fourth conductive structure 543 is disposed on the logic gate structure 500, and the fourth conductive structure 543 is in contact with the contact layer 480 on the top surface of the logic gate structure 500. The fifth conductive structure 544 is in contact with the contact layer 480 on the surface of the substrate 300 on two sides of the logic gate structure 500.

Accordingly, an embodiment of the present disclosure provides a memory structure formed by the above method. Still referring to FIG. 18, the memory structure includes: a substrate 300, a plurality of composite structures 400 disposed on the substrate 300 and separated from each other, a plurality of mutually independent source doped regions 360 disposed in the substrate 300, and a word line structure 430. A first opening 333 (as shown in FIG. 14) is formed between adjacent composite structures 400. Each composite structure 400 includes a first conductive structure 370, a floating gate structure 410 disposed on two sides of the first conductive structure 370, an erasing gate structure 420 disposed on the floating gate structure 410, and a first isolation structure 340, a second isolation structure 350 and a third isolation structure 380 disposed on the erasing gate structure 420. The second isolation structure 350 is disposed between the first conductive structure 370, the floating gate structure 410, the erasing gate structure 420 and the first isolation structure 340, and the third isolation structure 380 is disposed on the side surfaces of the first isolation structure 340, the erasing gate structure 420 and the floating gate structure 410. The inner wall surface of the first opening 333 exposes the side surface of the third isolation structure 380 and the surface of the substrate 300. The plurality of source doped regions 360 are in contact with the bottom surfaces of the first conductive structure 370 and the floating gate structure 410. The word line structure 430 is disposed in the first opening 333.

Specifically, since the composite structure 400 includes the first conductive structure 370 and the floating gate structure 410 disposed on two sides of the first conductive structure 370, and the plurality of mutually independent source doped regions 360 are disposed in the substrate 300, and the plurality of source doped regions 360 are in contact with the bottom surfaces of the first conductive structure 370 and the floating gate structure 410, voltage coupling to the floating gate structure 410 is realized. Moreover, since the composite structure 400 includes the floating gate structure 410 disposed on two sides of the first conductive structure 370, the erasing gate structure 420 disposed on the floating gate structure 410, and the memory structure also includes the word line structure 430 disposed in the first opening 333, the memory structure can erase data based on the erasing gate structure 420, so that the word line structure 430 can only be used for reading data, thus the reading voltage of the memory structure is low, the risk of interference when reading data is low, and the data reading accuracy is high.

On the basis of this, on the one hand, in the memory structure, since the erasing gate structure 420 of the composite structure 400 is disposed on the floating gate structure 410, a space is provided for the first conductive structure 370, so that the first conductive structure 370 can be disposed between split gates (i.e. the floating gate structure 410 and the erasing gate structure 420 on two sides), and can contact (connect) with the source doped regions 360 disposed in the substrate 300 below and between the split gates to directly lead out the source doped regions 360. In addition, the parasitic resistance at the source doped regions 360 and the first conductive structure 370 above the source dopes regions 360 is low, which improves the performance of the memory structure. On the other hand, since the source doped regions 360 can be directly led out through the first conductive structure 370, the plurality of source doped regions 360 can be independent of each other (that is, the source doped regions 360 can be isolated), and each source doped region 360 can only be disposed in the substrate 300 below the first conductive structure 370 and the floating gate structure 410, so that structures for leading out the plurality of source doped regions 360 are not needed in the substrate 300 outside a part of the substrate 300 below the composite structures 400, which can reduce the additional occupied area of the substrate 300 and improve the integration degree.

To sum up, the present disclosure can improve the performance and integration of the memory structure while achieving a low reading voltage of the memory structure, a low risk of interference when reading data, and a high accuracy of data reading.

In addition, since the plurality of source doped regions 360 can be independent of each other (that is, each source doped region 360 can be isolated), and each source doped region 360 can only be disposed in the substrate 300 below the first conductive structure 370 and the floating gate structure 410, the pattern of the source doped regions 360 is simple, and the plurality of source doped regions 360 can be formed by self-alignment, thus the forming process for the memory structure can be simplified.

In some embodiments, the substrate 300 includes a memory area I and a logic area II.

The memory area I is used to form a memory structure, and the logic area II is used to form a logic circuit for logic control of the memory structure.

Accordingly, in some embodiments, the composite structures 400, the first opening 333 and the word line structure 430 are disposed on the memory area I, and the source doped regions 360 are disposed in the memory area I.

In some embodiments, the material of the substrate 300 is silicon; in other embodiments, the material of the substrate can also be germanium, silicon germanium, silicon carbide, gallium arsenide or indium gallium.

In some embodiments, the material of the first conductive structure 370 includes polysilicon.

In some embodiments, the memory structure also includes a second protective layer 371 disposed on the top surface of the first conductive structure 370.

In some embodiments, the material of the second protective layer 371 includes silicon oxide.

In some embodiments, the floating gate structure 410 includes the floating gate dielectric layer 411 and the floating gate electrode 412 disposed on the floating gate dielectric layer 411.

In some embodiments, the material of the floating gate dielectric layer 411 includes silicon oxide.

In some embodiments, the material of the floating gate electrode 412 includes polysilicon.

In some embodiments, the erasing gate structure 420 includes the tunneling dielectric layer 421 and the erasing gate electrode 422 disposed on the tunneling dielectric layer 421.

Specifically, data erasure is achieved by pulling out electrons through a window between the erasing gate electrode 422 and the floating gate structure 410.

In some embodiments, the material of the tunneling dielectric layer 421 includes silicon oxide.

In some embodiments, the material of the erasing gate electrode 422 includes polysilicon.

In some embodiments, the width W1 of the erasing gate electrode 422 is less than the width W2 of the floating gate structure 410.

In some embodiments, a width of the tunneling dielectric layer 421 is greater than a width W1 of the erasing gate electrode 422 (as shown in FIG. 12).

Specifically, in a side of the erasing gate structure 420 adjacent to the third isolation structure 380, a side of the erasing gate electrode 422 is concave relative to a side of the tunneling dielectric layer 421.

Specifically, the width of the tunneling dielectric layer 421 is equal to the width W2 of the floating gate structure 410.

In some embodiments, the material of the first isolation structure 340 may include a dielectric material.

In some embodiments, the material of the first isolation structure 340 includes silicon oxide.

In some embodiments, the material of the second isolation structure 350 includes silicon oxide.

In some embodiments, the memory structure also includes a first protective layer 351 disposed between the second isolation structure 350 and the first conductive structure 370.

In some embodiments, the material of the first protective layer 351 is the same as that of the subsequently formed first conductive structure in order to ensure the stability of the conductivity.

Specifically, the material of the first protective layer 351 includes polysilicon.

In other embodiments, the material of the first conductive layer includes silicon nitride.

In other embodiments, the first protective layer is not formed.

In some embodiments, the third isolation structure 380 includes a first side wall 381 disposed on the side surfaces of the first isolation structure 350 and the erasing gate electrode 422.

The material of the first side wall 381 includes a dielectric material.

In some embodiments, the material of the first side wall 381 includes silicon oxide.

In some embodiments, the third isolation structure 380 also includes a second side wall 382 disposed on the side surfaces of the first side wall 381, the tunneling dielectric layer 421 and the floating gate structure 410, and the first opening 333 exposes the side surface of the second side wall 382.

The material of the second side wall 382 includes a dielectric material.

In some embodiments, the material of the second side wall 382 includes silicon oxide.

In some embodiments, the word line structure 430 includes the word line dielectric film 431a disposed on the inner wall surface of the first opening 333, and two word line films 433 respectively disposed on the opposite side surfaces of the word line dielectric film 431a. As shown in FIG. 17, the word line opening 434 is formed between the two word line films 433, and the side surfaces of the two word line films 433 and a part of the surface of the word line dielectric film 431a on the bottom surface of the first opening 333 are exposed through the word line opening 434.

In some embodiments, the material of the word line dielectric film 431a includes silicon oxide.

In some embodiments, the material of the word line films 433 includes polysilicon.

In some embodiments, the memory structure also includes a third side wall 460 disposed on the side surface of the word line films 433.

In some embodiments, the material of the third side wall 460 includes a dielectric material. Specifically, the material of the third side wall 460 includes silicon oxide.

In other embodiments, the third side wall is not formed.

In some embodiments, the memory structure also includes a plurality of logic gate structures 500 disposed on the logic area II.

In some embodiments, the plurality of logic gate structures 500 are used to form a plurality of high voltage MOS tubes and a plurality of low voltage MOS tubes.

In other embodiments, the substrate does not include the logic area and does not have the logic gate structure.

In some embodiments, the memory structure also includes a fourth side wall 510 disposed on the side wall of the logic gate structure 500.

In other embodiments, the fourth side wall is not formed.

In some embodiments, the memory structure also includes a contact layer 480 disposed on the top surface of the first conductive structure 370.

In some embodiments, the contact layer 480 is also disposed on the top surface of the word line films 433, the surface of the substrate 300 between the two word line films 433, the top surface of the logic gate structure 500, and the surface of the substrate 300 on two sides of the logic gate structure 500.

In some embodiments, the material of the contact layer 480 includes a metal silicide.

In other embodiments, the contact layer is not formed.

In some embodiments, the memory structure also includes an interlayer dielectric layer 520 disposed on the composite structure 400 and the word line structure 430. A surface of the interlayer dielectric layer 520 is higher than a top surface of the composite structure 400.

In some embodiments, the memory structure also includes a plurality of bit lines 530 disposed in the interlayer dielectric layer 520, and the bit lines 530 are also disposed in the word line opening 434.

In some embodiments, the bottom surfaces of the bit lines 530 are in contact with the contact layer 480 on the surface of the substrate 300 between the two word line films 433. In other embodiments, there is no contact layer, and the bit lines 530 are in contact with the surface of the substrate between the two word line films.

In some embodiments, the memory structure also includes a second conductive structure 541 disposed in the interlayer dielectric layer 520. The second conductive structure 541 is also disposed on the first conductive structure 370, and the second conductive structure 541 is in contact with the contact layer 480 disposed on the top surface of the first conductive structure 370.

In some embodiments, the memory structure also includes a third conductive structure 542 disposed in the interlayer dielectric layer 520 on the memory area I. The third conductive structure 542 is also disposed on the word line films 433, and the third conductive structure 542 is in contact with the contact layer 480 disposed on the top surface of the word line films 433.

In some embodiments, the memory structure also includes a fourth conductive structure 543 and a fifth conductive structure 544 disposed in the interlayer dielectric layer 520 on the logic area II. The fourth conductive structure 543 is also disposed on the logic gate structure 500 and is in contact with the contact layer 480 disposed on the top surface of the logic gate structure 500. The fifth conductive structure 544 is in contact with the contact layer 480 disposed on the surface of the substrate 300 on two sides of the logic gate structure 500.

Although the present disclosure has been disclosed above, the present disclosure is not limited thereto. Any changes and modifications may be made by those skilled in the art without departing from the spirit and scope of the present disclosure, and the scope of the present disclosure should be determined by the appended claims.

1. A method for forming a memory structure, comprising:
providing a substrate;
forming a plurality of discrete composite structures on the substrate, wherein a first opening is formed between adjacent composite structures, and each composite structure comprises a first conductive structure, a floating gate structure disposed on both sides of the first conductive structure, an erasing gate structure disposed on the floating gate structure, a first isolation structure, a second isolation structure and a third isolation structure disposed on the erasing gate structure, wherein the second isolation structure is disposed between the first conductive structure and the floating gate structure, the erasing gate structure and the first isolation structure, the third isolation structure is disposed on side surfaces of the first isolation structure, the erasing gate structure and the floating gate structure, and a side surface of the third isolation structure and a surface of the substrate are exposed through an inner wall surface of the first opening;
forming a plurality of mutually independent source doped regions in the substrate during forming the plurality of composite structures, wherein the plurality of source doped regions are in contact with bottom surfaces of the first conductive structure and the floating gate structure; and
forming a word line structure in the first opening after forming the plurality of composite structures.

2. The method according to claim 1, wherein forming the plurality of composite structures comprises:
forming an initial floating gate layer on the substrate, an initial erasing gate layer on the initial floating gate layer, and a mask layer on the initial erasing gate layer, wherein the mask layer is provided with a plurality of mask openings, a part of a surface of the initial erasing gate layer is exposed through the plurality of mask openings;
forming the first isolation structure on side surfaces of the plurality of mask openings;
etching the initial erasing gate layer and the initial floating gate layer with the mask layer and the first isolation structure as a mask until the surface of the substrate is exposed so that a third opening is formed in the initial erasing gate layer and the initial floating gate layer;
forming the second isolation structure on side surfaces of the first isolation structure and the third opening; and
forming the first conductive structure in the plurality of mask openings and the third opening and forming a second protective layer on a top surface of the first conductive structure after forming the second isolation structure.

3. The method according to claim 2, further comprising: forming a first protective layer on a side surface of the second isolation structure during forming the second isolation structure.

4. The method according to claim 3, wherein forming the second isolation structure comprises:
forming a second isolation structure material film on a surface of the mask layer, a surface of the first isolation structure and an inner wall surface of the third opening;
forming a first protective material film on a surface of the second isolation structural material film; and
etching the first protective material film and the second isolation structure material film by an anisotropic etching process until a top surface of the mask layer and a bottom surface of the third opening are exposed.

5. The method according to claim 2, wherein forming the plurality of mutually independent source doped regions in the substrate during forming the plurality of composite structures comprises:
performing an ion implantation on the substrate exposed through a bottom of the third opening with the mask layer, the first isolation structure and the second isolation structure as a mask before forming the first conductive structure; and
diffusing the implanted ions into the substrate below the initial floating gate layer on two sides of the third opening.

6. The method according to claim 2, wherein forming the plurality of composite structures further comprises:
removing the mask layer after forming the first conductive structure and the second protective layer;
patterning the initial erasing gate layer according to the second protective layer and the first isolation structure to form the erasing gate structure after removing the mask layer; and
patterning the initial floating gate layer according to the second protective layer and the first isolation structure to form the floating gate structure after forming the erasing gate structure.

7. The method according to claim 6, wherein the initial erasing gate layer comprises an initial tunneling dielectric layer and an initial erasing gate electrode layer on the initial tunneling dielectric layer, and the erasing gate structure comprises a tunneling dielectric layer and an erasing gate electrode on the tunneling dielectric layer.

8. The method according to claim 7, wherein the third isolation structure comprises: a first side wall on side surfaces of the first isolation structure and the erasing gate electrode, and a second side wall on side surfaces of the first side wall, the tunneling dielectric layer and the floating gate structure, and a side surface of the second side wall is exposed through the first opening.

9. The method according to claim 8, wherein forming the third isolation structure comprises:
forming the first side wall during patterning the initial erasing gate layer according to the second protective layer and the first isolation structure to form the erasing gate structure; and
forming the second side wall on the side surfaces of the first side wall, the tunneling dielectric layer and the floating gate structure after forming the floating gate structure.

10. The method according to claim 9, wherein patterning the initial erasing gate layer according to the second protective layer and the first isolation structure to form the erasing gate structure comprises:
etching the initial erasing gate electrode layer with the second protective layer and the first isolation structure as a mask until a surface of the initial tunneling dielectric layer is exposed to form the erasing gate electrode;
forming the first side wall on the side surfaces of the first isolation structure and the erasing gate electrode; and
etching the initial tunneling dielectric layer with the second protective layer, the first isolation structure and the first side wall as a mask until a surface of the initial floating gate layer is exposed to form the tunneling dielectric layer.

11. The method according to claim 9, wherein patterning the initial floating gate layer according to the second protective layer and the first isolation structure to form the floating gate structure after forming the erasing gate structure comprises:
etching the initial floating gate layer with the second protective layer, the first isolation structure and the first side wall as a mask until the surface of the substrate is exposed.

12. The method according to claim 1, wherein forming the word line structure in the first opening after forming the plurality of composite structures comprises:
forming a word line dielectric material film on the plurality of composite structures and an inner wall surface of the first opening, wherein the word line dielectric material film on the inner wall surface of the first opening is taken as a word line dielectric film;
forming an initial word line film on a surface of the word line dielectric material film;
etching the initial work line film by an anisotropic etching process until a surface of the word line dielectric film is exposed through a bottom surface of the first opening; and
forming two word line films on opposite side surfaces of the word line dielectric film, wherein a word line opening is formed between the two word line films, and side surfaces of the two word line films and a part of a surface of the word line dielectric film on the bottom surface of the first opening are exposed through the word line opening.

13. The method according to claim 12, further comprising:
forming a third side wall on the side surfaces of the two word line films after forming the word line structure.

14. The method according to claim 12, further comprising:
forming an interlayer dielectric layer on the plurality of composite structures and the word line structure after forming the word line structure, wherein a surface of the interlayer dielectric layer is higher than a top surface of the plurality of composite structures; and
forming a plurality of bit lines in the interlayer dielectric layer, wherein the plurality of bit lines are also disposed in the word line opening.

15. The method according to claim 1, further comprising:
forming a contact layer on a top surface of the first conductive structure after forming the word line structure.

16. A memory structure formed by the method according to claim 1, comprising:
the substrate;
the plurality of discrete composite structures disposed on the substrate, wherein the first opening is formed between adjacent composite structures, and each composite structure comprises the first conductive structure, the floating gate structure disposed on both sides of the first conductive structure, the erasing gate structure disposed on the floating gate structure, the first isolation structure, the second isolation structure and the third isolation structure disposed on the erasing gate structure, wherein the second isolation structure is disposed between the first conductive structure and the floating gate structure, the erasing gate structure and the first isolation structure, the third isolation structure is disposed on side surfaces of the first isolation structure, the erasing gate structure and the floating gate structure, and the side surface of the third isolation structure and the surface of the substrate are exposed through the inner wall surface of the first opening;
the plurality of mutually independent source doped regions disposed in the substrate, wherein the plurality of source doped regions are in contact with the bottom surfaces of the first conductive structure and the floating gate structure; and
the word line structure disposed in the first opening.

17. The memory structure according to claim 16, wherein the floating gate structure comprises a floating gate dielectric layer and a floating gate electrode disposed on the floating gate dielectric layer.

18. The memory structure according to claim 16, wherein the erasing gate structure comprises a tunneling dielectric layer and an erasing gate electrode disposed on the tunneling dielectric layer.

19. The memory structure according to claim 18, wherein a width of the erasing gate electrode is less than a width of the floating gate structure.

20. The memory structure according to claim 19, wherein in a side of the erasing gate structure adjacent to the third isolation structure, a side of the erasing gate electrode is recessed relative to a side of the tunneling dielectric layer.
